(19) United States
(12) Patent Application Publication
(10) Pub. No.: US 2026/0215363 A1
(43) Pub. Date: Jul. 30, 2026

(54) CELL HOUSING, BATTERY, HEAT DISSIPATION ASSEMBLY FOR LAWN MOWER, MOWING ASSEMBLY, AND LAWN MOWER

(71) Applicant: SHENZHEN ZONGGUAN INNOVATION CO., LTD., Shenzhen (CN)

(72) Inventors: Zhenkai WU, Shenzhen (CN); Yonggen WANG, Shenzhen (CN)

(73) Assignee: SHENZHEN ZONGGUAN INNOVATION CO., LTD., Shenzhen (CN)

(21) Appl. No.: 19/570,104

(22) Filed: Mar. 17, 2026

Related U.S. Application Data
(63) Continuation of application No. PCT/CN2024/079992, filed on Mar. 4, 2024.

(30) Foreign Application Priority Data
Oct. 10, 2023 (CN) 202322721451.1
Oct. 10, 2023 (CN) 202322739278.8

(51) Int. Cl. A01D 34/82; A01D 34/78; A01D 101/00; H01M 10/48; H01M 10/613; H01M 10/625; H01M 10/6563; H01M 50/242; H01M 50/249; H01M 50/256; H02K 9/06

(52) U.S. Cl. CPC A01D 34/82; A01D 34/78; H01M 10/488; H01M 10/613; H01M 10/625; H01M 10/6563; H01M 50/242; H01M 50/249; H01M 50/256; H02K 9/06; A01D 2101/00; H01M 2220/20

(57) ABSTRACT

The present disclosure provides a cell housing that includes a housing and also relates to a heat dissipation assembly, a mowing assembly, and a lawn mower using the same.. Four corners of the housing are detachably connected to anti-collision members each including a first transverse anti-collision part, a vertical anti-collision part, and a second transverse anti-collision part. The vertical anti-collision part is configured to surround a side of the housing. The first transverse anti-collision part and the second transverse anti-collision part extend horizontally, from upper and lower ends of the vertical anti-collision part, in a direction away from the vertical anti-collision part, and are configured to surround upper and lower ends of the housing, respectively.

### CROSS-REFERENCE TO RELATED APPLICATION

This application is a continuation of International Application No. PCT/CN2024/079992, filed on Mar. 4, 2024, which claims the benefit of priority to Chinese Patent Application No.202322739278.8, filed on Oct. 10, 2023, and to Chinese Patent Application No. 202322721451.1, filed on Oct. 10, 2023. The contents of the above-referenced applications are hereby incorporated by reference in their entireties.

### BACKGROUND

The present disclosure relates to the technical field of lawn mowers, and in particular, to a cell housing, battery, heat dissipation assembly for a lawn mower, mowing assembly, and lawn mower.

A lawn mower is a mechanical tool configured to trim lawns and vegetation. Lawn mowers are commonly used in parks, farms, and other places with large lawn areas. The traveling mechanism of the lawn mower drives the lawn mower to move in the lawn, while the blade rotates at high speed under the drive of the mowing motor to perform mowing. The rotational speed of the mowing motor corresponds to the rotational speed of the blade. Therefore, the rotational speed of the blade needs to be adjusted by controlling the mowing motor, and the control of the mowing motor needs to be realized by a corresponding driver.

The mowing motor and the driver generate a large amount of heat when the blade is running at high speed, and need to be cooled to maintain stable performance. However, in existing lawn mowers, the mowing motor and the corresponding driver are often far apart, and both the motor and the driver require separate heat dissipation modules for cooling, resulting in high cost.

### SUMMARY

The main purpose of the present disclosure is to provide a cell housing, battery, heat dissipation assembly for a lawn mower, mowing assembly, and lawn mower.

A cell housing is provided, including a housing. Four corners of the housing are detachably connected to anti-collision members. The anti-collision member includes a first transverse anti-collision part, a vertical anti-collision part, and a second transverse anti-collision part. The vertical anti-collision part wraps around a side of the housing. The first transverse anti-collision part and the second transverse anti-collision part extend horizontally and transversely from the upper and lower ends of the vertical anti-collision part in a direction away from the vertical anti-collision part. The first transverse anti-collision part and the second transverse anti-collision part wrap around the upper and lower ends of the housing, respectively.

Based on the same concept, the present disclosure also provides a battery, including a cell and the above cell housing.

Based on the same concept, the present disclosure also provides a lawn mower, including the above battery.

A heat dissipation assembly for a lawn mower is also provided, including a heat dissipation housing and heat dissipation fan blades. The heat dissipation housing includes a first chamber and a second chamber arranged adjacently. The first chamber is configured to arrange a mowing motor of the lawn mower. The second chamber is configured to arrange a driver of the mowing motor. The heat dissipation fan blades are connected to an output shaft of the mowing motor. An air inlet hole is arranged on the heat dissipation housing outside the second chamber. A heat dissipation air duct communicates with the mowing motor and the driver. An air outlet hole is arranged on the heat dissipation housing at the lower end of the mowing motor. The heat dissipation fan blades are configured to direct airflow entering through the air inlet hole through the heat dissipation air duct, and then flow out from the air outlet hole.

Based on the same concept, the present disclosure also provides a mowing assembly, including the above heat dissipation assembly, as well as a mowing motor, a driver, and a mowing blade. The mowing motor is arranged within the first chamber of the heat dissipation housing. The driver is arranged within the second chamber. The driver is electrically connected to the mowing motor. The driver is configured to control the operation of the mowing motor. The mowing blade and the heat dissipation fan blades are both connected to the output shaft of the mowing motor. The heat dissipation fan blades are adjacent to the mowing motor. The mowing blade is farther from the mowing motor.

Based on the same concept, the present disclosure also provides a lawn mower, including the above mowing assembly.

### BRIEF DESCRIPTION OF DRAWINGS

FIG. 1 is a structural schematic diagram of the cell housing in some implementations of the present disclosure.

FIG. 2 is an exploded structural schematic diagram of the cell housing in some implementations of the present disclosure.

FIG. 3 is another structural schematic diagram of the cell housing in some implementations of the present disclosure.

FIG. 4 is a bottom view structural schematic diagram of the cell housing in some implementations of the present disclosure.

FIG. 5 is a structural schematic diagram of the outer side of the anti-collision member in some implementations of the present disclosure.

FIG. 6 is a structural schematic diagram of the inner side of the anti-collision member in some implementations of the present disclosure.

FIG. 7 is a structural schematic diagram of the connecting rib in one implementation in some implementations of the present disclosure.

FIG. 8 is a structural schematic diagram of the heat dissipation assembly in some implementations of the present disclosure.

FIG. 9 is an exploded structural schematic diagram of the heat dissipation assembly in some implementations of the present disclosure.

FIG. 10 is a structural schematic diagram of the mounting frame in some implementations of the present disclosure.

FIG. 11 is a structural schematic diagram of the mowing motor in some implementations of the present disclosure.

FIG. 12 is a structural schematic diagram of the heat dissipation fan blades in some implementations of the present disclosure.

FIG. 13 is a structural schematic diagram of the mowing assembly in some implementations of the present disclosure.

FIG. 14 is an exploded structural schematic diagram of the mowing assembly in some implementations of the present disclosure.

### DETAILED DESCRIPTION

In order to facilitate understanding of the present disclosure, the following provides a more detailed description of the present disclosure in conjunction with the drawings and specific implementations. Preferred implementations of the present disclosure are shown in the drawings. However, the present disclosure can be implemented in many different forms and is not limited to the implementations described in this specification. On the contrary, the purpose of providing these implementations is to make the disclosure of the present disclosure more thorough and comprehensive.

It should be noted that, unless otherwise defined, all technical and scientific terms used in this specification have the same meaning as commonly understood by those skilled in the art to which the present disclosure belongs. The terms used in the specification of the present disclosure are only for the purpose of describing specific implementations and are not intended to limit the present disclosure. The term “and/or” as used in this specification includes any and all combinations of one or more of the associated listed items.

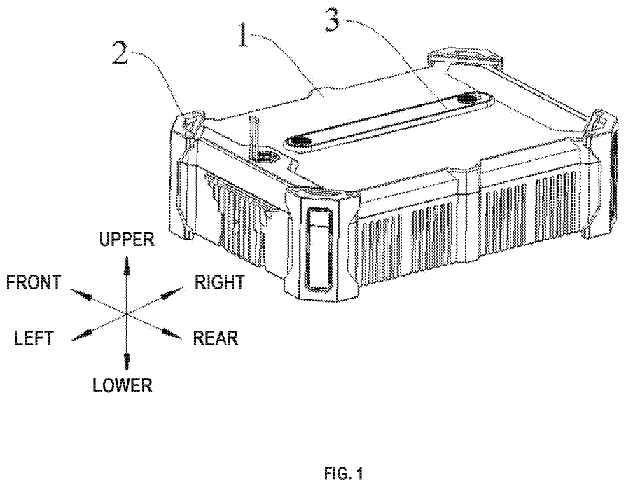

For the description of the present disclosure, the non-limiting labels “front,” “rear,” “upper,” “lower,” “left,” and “right” as shown in FIG. 1 are used to facilitate understanding of the implementation and are not intended to limit the present disclosure. The front-rear direction indicates the longitudinal direction, the left-right direction indicates the transverse direction, and the upper-lower direction indicates the vertical direction.

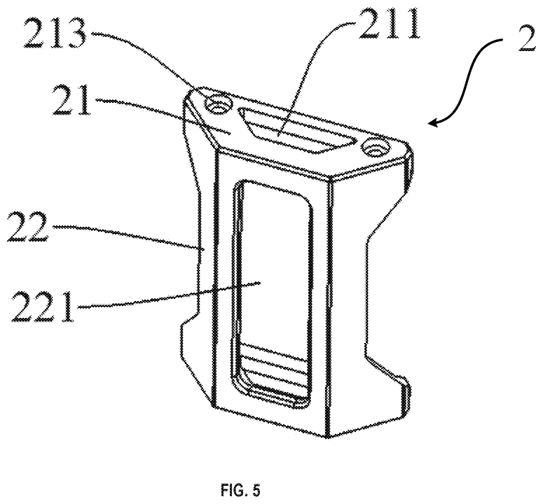

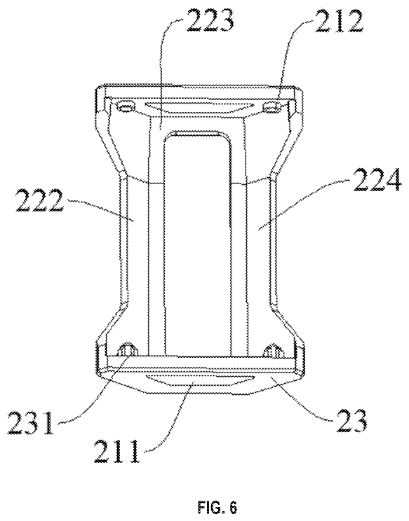

FIGS. 1 to 7 show implementations of the cell housing, battery, and lawn mower of the present disclosure, including a housing 1. Four corners of the housing 1 are detachably connected to anti-collision members 2. The anti-collision member 2 includes a first transverse anti-collision part 21, a vertical anti-collision part 22, and a second transverse anti-collision part 23. The vertical anti-collision part 22 wraps around or surrounds a side of the housing 1. The first transverse anti-collision part 21 and the second transverse anti-collision part 23 extend horizontally and transversely from the upper and lower ends of the vertical anti-collision part 22 in a direction away from the vertical anti-collision part 22. The first transverse anti-collision part 21 and the second transverse anti-collision part 23 wrap around or surround the upper and lower ends of the housing 1, respectively.

In the present disclosure, by providing detachable anti-collision members 2 at the four corners of the housing 1, the first transverse anti-collision part 21 and the second transverse anti-collision part 23 of the anti-collision member 2 wrap around or surround the upper and lower ends of the four corners of the housing 1. The vertical anti-collision part 22 wraps around or surrounds the side of the four corners of the housing 1. When a collision occurs, the anti-collision member 2 acts as a buffer to prevent deformation or damage of the housing 1, thereby better protecting the cell.

The anti-collision member 2 is made of soft rubber material, which is difficult to position when installed on the housing 1, therefore making installation relatively troublesome.

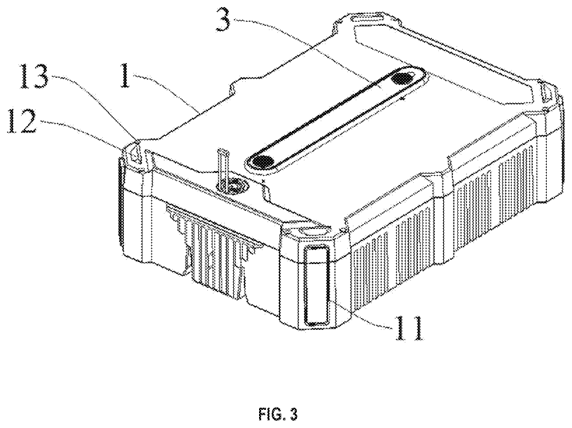

In one implementation, as shown in FIGS. 3, 5, and 6, a vertical positioning hole 221 is provided in the middle of the vertical anti-collision part 22. A corresponding position on the housing 1 is provided with a vertical positioning protrusion 11. The vertical positioning protrusion 11 is engaged in the vertical positioning hole 221. By engaging the vertical positioning protrusion 11 with the vertical positioning hole 221, preliminary positioning of the anti-collision member 2 is achieved, facilitating the installation of the anti-collision member 2.

The vertical anti-collision part 22 further includes a first vertical sub-part 222, a second vertical sub-part 223, and a third vertical sub-part 224. The second vertical sub-part 223 is located in the middle. The first vertical sub-part 222 and the third vertical sub-part 224 extend transversely from the left and right ends of the second vertical sub-part 223, respectively. The first vertical sub-part 222, the second vertical sub-part 223, and the third vertical sub-part 224 together provide all-around protection for the side of the housing 1. The vertical positioning hole 221 is located in the middle of the second vertical sub-part 223. The first vertical sub-part 222 and the third vertical sub-part 224 have the same shape. The width of the upper and lower ends of the first vertical sub-part 222 and the third vertical sub-part 224 is less than the width of the middle part. This saves material while still providing protection for the housing 1.

In one implementation, as shown in FIGS. 3 to 6, both the first transverse anti-collision part 21 and the second transverse anti-collision part 23 are provided with a limit hole 211. The two limit holes 211 are located in the middle of the first transverse anti-collision part 21 and the second transverse anti-collision part 23, respectively. The shape of the limit hole 211 can be trapezoidal. A corresponding position on the housing 1 is provided with a limit protrusion 12. The limit protrusion 12 is engaged in the limit hole 211. By engaging the limit protrusion 12 in the limit hole 211, detachment of the anti-collision member 2 is prevented.

In one implementation, as shown in FIGS. 3 to 6, the first transverse anti-collision part 21 extends downward to form a first positioning column 212. Two first positioning columns 212 are located on both sides of the first transverse anti-collision part 21, respectively. The housing 1 is provided with a first positioning hole 13 adapted to or corresponding to the first positioning column 212. The first positioning column 212 is engaged in the first positioning hole 13. By engaging the first positioning column 212 in the first positioning hole 13, the positioning of the upper end of the anti-collision member 2 is achieved, facilitating the installation of the anti-collision member 2.

At the position of the upper end of the first transverse anti-collision part 21 corresponding to the first positioning column 212, a mounting groove 213 is further provided. The anti-collision member 2 can be fixedly connected to the housing 1 by screws at the mounting groove 213. At this time, the nut is just engaged in the mounting groove 213 and does not protrude from the upper surface of the first transverse anti-collision part 21.

In one implementation, as shown in FIGS. 3 to 6, the second transverse anti-collision part 23 extends upward to form a second positioning column 231. Two second positioning columns 231 are located on both sides of the second transverse anti-collision part 23, respectively. The housing 1 is provided with a second positioning hole 14 adapted to or corresponding to the second positioning column 231. The second positioning column 231 is engaged in the second positioning hole 14. By engaging the second positioning column 231 in the second positioning hole 14, the positioning of the lower end of the anti-collision member 2 is achieved, facilitating the installation of the anti-collision member 2.

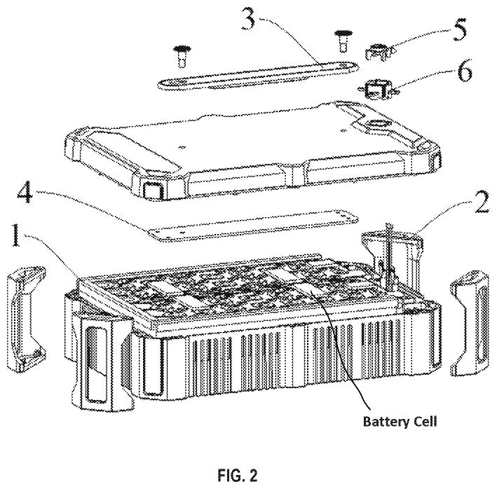

In one implementation, as shown in FIG. 2, the housing 1 further includes a handle 3. The handle 3 is arranged at the middle of the upper end of the housing 1. A fixing plate 4 adapted to or corresponding to the handle 3 is arranged inside the housing 1. The fixing plate 4 is a steel plate. The handle 3 passes through the housing 1 and is fixedly connected to the fixing plate 4. By pulling the handle 3, the housing 1 can be quickly moved, which is more convenient. The handle 3 is fixedly connected to the fixing plate 4 inside the housing 1. Compared with directly connecting to the housing 1, this can avoid all the pulling force being applied to the housing 1, preventing stress concentration and cracking of the housing 1 during lifting.

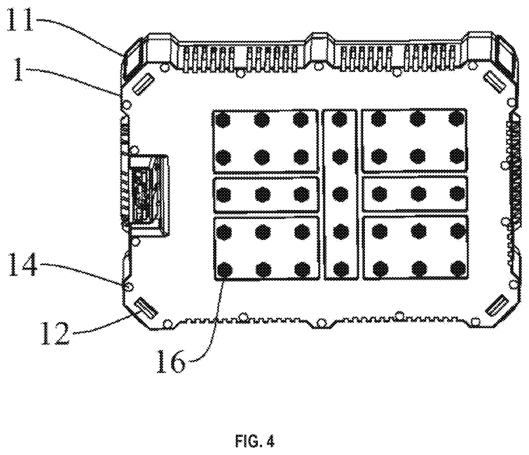

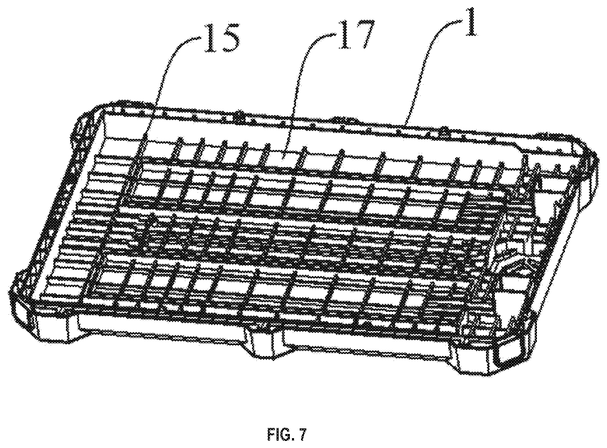

In one implementation, as shown in FIGS. 4 and 7, a reinforcing rib 15 is arranged on the inner side of the top of the housing 1. In some implementations, multiple reinforcing ribs 15 can be disposed on the housing 1 to increase the strength of the housing 1 and prevent deformation of the housing 1, as shown in FIG. 7. A vent hole 16 is arranged at the bottom of the housing 1. In some implementations, multiple vent holes 16 can be arranged at the bottom of the housing 1. The vent hole 16 is configured for heat dissipation inside the housing 1. Multiple reinforcing ribs 15 are arranged side by side to form an air duct 17. The air duct 17 is configured to guide air to flow out of the housing 1. After the cell is installed in the housing 1, air entering the housing 1 from the vent hole 16 flows through the gaps between the cells to the upper part of the housing 1, and then is guided by the air duct 17 to flow out from inside the housing 1, thereby achieving rapid heat dissipation for the cell.

In one implementation, as shown in FIG. 2, the cell housing further includes a silicone button 5 and a light guide post 6. The silicone button 5 and the light guide post 6 are located within the housing 1. The silicone button 5 is engaged in the light guide post 6. The upper ends of the silicone button 5 and the light guide post 6 are exposed on the upper surface of the housing 1. The silicone button 5 is configured to control the on-off of the battery. At the same time, the silicone material has a better waterproof effect, which can prevent water from entering the housing 1 from the silicone button 5. The lower end of the light guide post 6 is arranged adjacent to the circuit board. The light guide post 6 conducts the light from the circuit board to the upper end, thereby displaying the operating state of the battery.

Based on the same concept, the present disclosure also provides a battery, including a cell and the above cell housing.

Based on the same concept, the present disclosure also provides a lawn mower, including the above battery.

It can be seen that the present disclosure discloses a cell housing, a battery, and a lawn mower. By providing detachable anti-collision members at the four corners of the housing, the first transverse anti-collision part and the second transverse anti-collision part of the anti-collision member wrap around or surround the upper and lower ends of the four corners of the housing. The vertical anti-collision part wraps around or surrounds the side of the four corners of the housing. When a collision occurs, the anti-collision member acts as a buffer to prevent deformation or damage of the housing, thereby better protecting the cell.

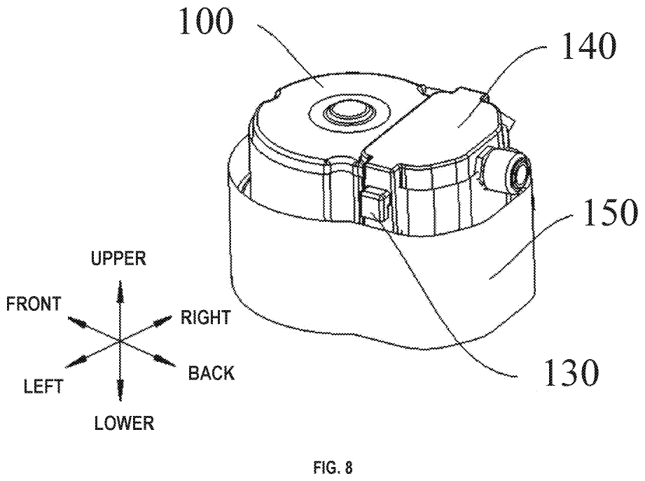

For the description of the present disclosure, the non-limiting labels “front,” “rear,” “upper,” “lower,” “left,” and “right” as shown in FIG. 8 are used to facilitate understanding of the implementation and are not intended to limit the present disclosure. The front-rear direction indicates the longitudinal direction, the left-right direction indicates the transverse direction, and the upper-lower direction indicates the vertical direction.

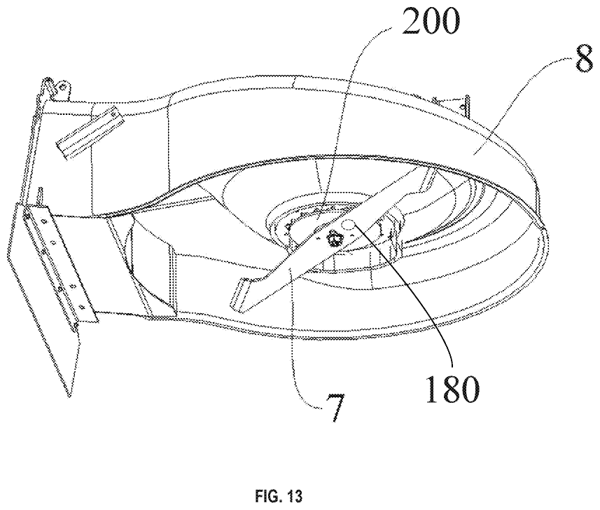

FIGS. 8 to 14 show implementations of the heat dissipation assembly for a lawn mower, mowing assembly, and lawn mower of the present disclosure, including a heat dissipation housing 100 and heat dissipation fan blades 200. The heat dissipation housing 100 includes a first chamber 110 and a second chamber 120 arranged adjacently between each other. The first chamber 110 is configured to arrange a mowing motor 300 of the lawn mower. The second chamber 120 is configured to arrange a driver 400 of the mowing motor 300. The heat dissipation fan blades 200 are connected to an output shaft of the mowing motor 300. An air inlet hole 130 is arranged on the heat dissipation housing 100 outside the second chamber 120. A heat dissipation air duct 500 communicates with the mowing motor 300 and the driver 400. An air outlet hole 180 (blocked by fan blades 200 and thus shown as a dotted circle in FIG. 13) is arranged on the heat dissipation housing 100 at the lower end of the mowing motor 300. The heat dissipation fan blades 200 are configured to direct airflow entering through the air inlet hole 130 through the heat dissipation air duct 500 and then flow out from the air outlet hole 180.

In the present disclosure, by arranging the mowing motor 300 and the driver 400 in the first chamber 110 and the second chamber 120 of the heat dissipation housing 100, respectively, and using the airflow generated by the high-speed rotation of the heat dissipation fan blades 200, air enters the heat dissipation housing 100 from the air inlet hole 130, flows through the heat dissipation air duct 500, and then flows out from the air outlet hole 180. Through continuous heat exchange, the mowing motor 300 and the driver 400 are cooled together, and the heat dissipation cost is low. Moreover, when the rotational speed of the mowing motor 300 increases, the heat generated by the driver 400 also increases. The heat dissipation fan blades 200 are connected to the output shaft of the mowing motor 300. The higher the rotational speed of the mowing motor 300, the higher the rotational speed of the heat dissipation fan blades 200, which matches the rotational speed of the mowing motor 300 for heat dissipation, resulting in a better heat dissipation effect.

The heat dissipation housing 100 can be of an integrated structure. However, when the heat dissipation housing 100 is of an integrated structure, it is inconvenient to repair and replace the internal equipment.

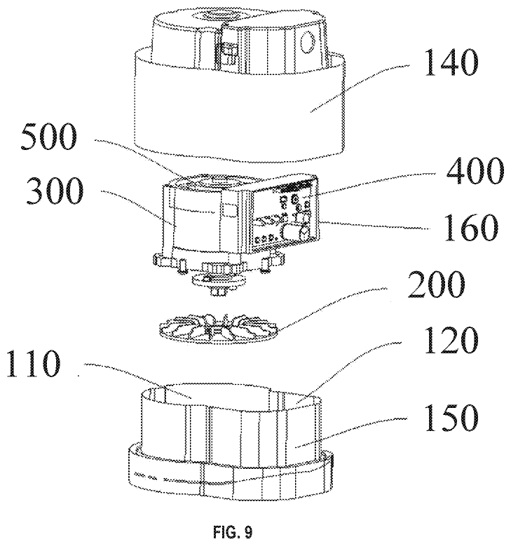

In some implementations, as shown in FIG. 9, the heat dissipation housing 100 includes an upper housing 140 and a lower housing 150. The upper housing 140 covers the lower housing 150 from above. The upper housing 140 is detachably connected to the lower housing 150. When it is necessary to repair or replace the internal mowing motor 300 or driver 400, the upper housing 140 can be directly opened, which is more convenient.

In some implementations, a sealing ring is arranged between the upper housing 140 and the lower housing 150. The sealing ring can prevent water and dust from entering the inside of the heat dissipation housing 100, thereby protecting the mowing motor 300 and the driver 400. At the same time, the sealing ring can prevent air leakage, so that when air flows inside the heat dissipation housing 100, it will not leak from the gap between the upper housing 140 and the lower housing 150, thereby improving heat exchange efficiency and achieving better heat dissipation effect.

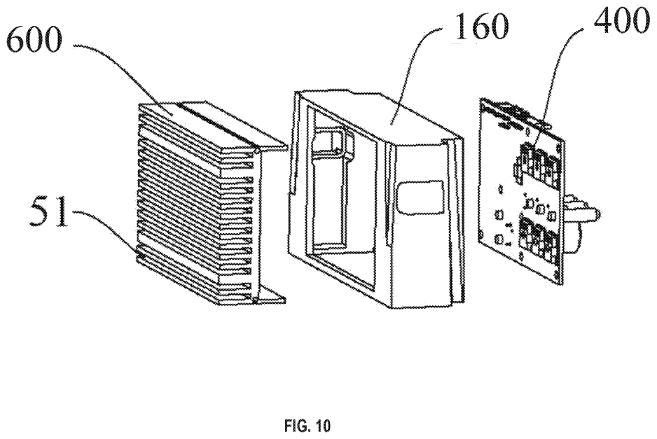

In some implementations, as shown in FIGS. 9 and 10, a mounting frame 160 is arranged within the second chamber 120. The mounting frame 160 is configured to mount the driver 400. By mounting the driver 400 on the mounting frame 160, the driver 400 can be placed vertically, increasing the heat dissipation area of the driver 400 and improving heat dissipation efficiency.

In some implementations, as shown in FIGS. 8 and 10, a heat sink 600 is arranged on the mounting frame 160 adjacent to the driver 400. The heat sink 600 is arranged in close contact with the back of the driver 400. The heat sink 600 is configured to dissipate heat from the driver 400. A plurality of first sub-air ducts 51 are arranged on the heat sink 600. The heat dissipation fan blades 200 are configured to direct airflow entering through the air inlet hole 130 through the first sub-air ducts 51 and then flow out from the air outlet hole 180. By arranging the heat sink 600 on the back of the driver 400, the heat of the driver 400 can be conducted to the heat sink 600, and then the heat is carried out of the heat dissipation housing 100 through heat exchange between the airflow and the heat sink 600, thereby achieving rapid heat dissipation for the driver 400 and improving heat dissipation efficiency.

In some implementations, as shown in FIGS. 8, 9, and 12, the heat dissipation fan blades 200 include a base plate portion 210 and a plurality of blade portions 220. The number of blade portions 220 can be adjusted according to actual needs. The blade portions 220 are uniformly and intermittently distributed on the base plate portion 210. The blade portions 220 extend in a direction towards the mowing motor 300. By arranging the blade portions 220 on the base plate portion 210, the overall structural strength of the heat dissipation fan blades 200 is increased. The blade portions 220 are adjacent to the bottom of the mowing motor 300. The centrifugal force generated by rotation draws air in from the air inlet hole 130, which then flows through the heat dissipation air duct 500 and is discharged from the air outlet hole 180, thereby carrying the heat of the mowing motor 300 and the driver 400 out of the heat dissipation housing 100 and achieving heat dissipation for the mowing motor 300 and the driver 400.

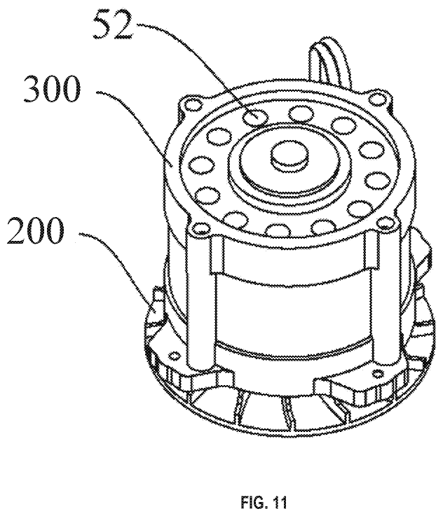

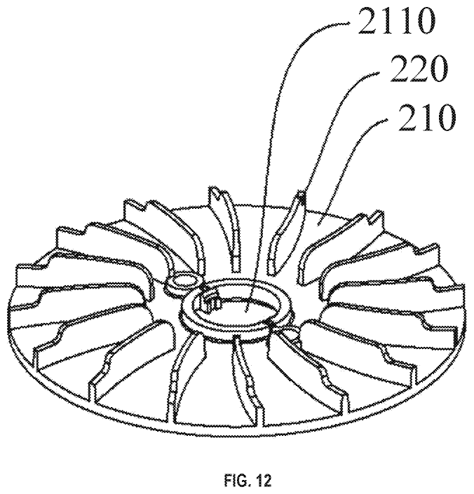

In some implementations, as shown in FIGS. 11 and 12, a connection hole 2110 is arranged at the center of the base plate portion 210. The connection hole 2110 is configured to connect the output shaft of the mowing motor 300. The rotation of the output shaft of the mowing motor 300 drives the rotation of the base plate portion 210, so that the plurality of blade portions 220 rotate to generate centrifugal force. The height of the blade portion 220 adjacent to the connection hole 2110 is greater than the height of the blade portion 220 farther from the connection hole 2110, which effectively reduces wind resistance during rotation of the blade portions 220, increases centrifugal force during rotation, and achieves better heat dissipation effect.

Based on the same concept, the present disclosure also provides a mowing assembly, as shown in FIGS. 9, 13, and 14, including the above heat dissipation assembly, as well as a mowing motor 300, a driver 400, and a mowing blade 7. The mowing motor 300 is arranged within the first chamber 110 of the heat dissipation housing 100. The driver 400 is arranged within the second chamber 120. The driver 400 is electrically connected to the mowing motor 300. The driver 400 is configured to control the operation of the mowing motor 300. The mowing blade 7 and the heat dissipation fan blades 200 are both connected to the output shaft of the mowing motor 300. The heat dissipation fan blades 200 are adjacent to the mowing motor 300. The mowing blade 7 is farther from the mowing motor 300. The mowing blade 7 and the heat dissipation fan blades 200 share the output shaft of the mowing motor 300. When the rotational speed of the mowing blade 7 increases, the load on the mowing motor 300 and the driver 400 increases, and the heat generated increases. At the same time, since the heat dissipation fan blades 200 are also connected to the output shaft of the mowing motor 300, the rotational speed of the heat dissipation fan blades 200 also increases, and the heat dissipation effect is enhanced accordingly, thereby achieving proportional heat dissipation for the mowing motor 300 and the driver 400. There is no need to separately control the rotational speed of the heat dissipation fan blades 200, which is more convenient.

In some implementations, as shown in FIG. 11, a plurality of second sub-air ducts 52 are arranged within the mowing motor 300. The plurality of second sub-air ducts 52 run through the mowing motor 300 from top to bottom. The second sub-air ducts 52 are configured to dissipate heat from the mowing motor 300. The second sub-air ducts 52 increase the heat dissipation area of the mowing motor 300. After the airflow flows through the top of the mowing motor 300, it enters the plurality of second sub-air ducts 52 and is then discharged from the bottom of the mowing motor 300, thereby achieving rapid heat dissipation for the mowing motor 300.

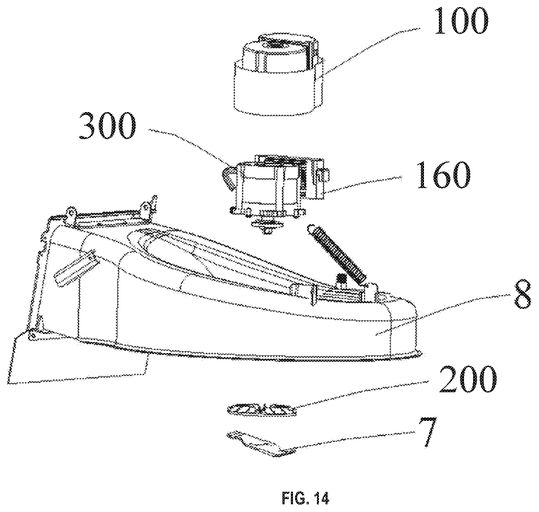

As shown in FIGS. 13 and 14, the mowing assembly further includes a blade deck frame 8. The heat dissipation housing 100 is located above the blade deck frame 8. The mowing blade 7 and the heat dissipation fan blades 200 are located below the blade deck frame 8. The output shaft of the mowing motor 300 extends into the blade deck frame 8 and is connected to the mowing blade 7 and the heat dissipation fan blades 200. The blade deck frame 8 is provided with a heat dissipation hole (not shown in the figures) at a position corresponding to the second sub-air ducts 52. The airflow from the second sub-air ducts 52 flows out from the heat dissipation hole into the blade deck frame 8 and is then discharged to the outside by the blade deck frame 8, thereby forming a heat dissipation air duct system composed of the heat dissipation housing 100, the mowing motor 300, the driver 400, and the blade deck frame 8, improving heat dissipation efficiency and achieving better heat dissipation effect.

Based on the same concept, the present disclosure also provides a lawn mower, including the above mowing assembly.

It can be seen that the present disclosure discloses a heat dissipation assembly for a lawn mower, a mowing assembly, and a lawn mower. By arranging the mowing motor and the driver in the first chamber and the second chamber of the heat dissipation housing, respectively, and using the airflow generated by the high-speed rotation of the heat dissipation fan blades, air enters the heat dissipation housing from the air inlet hole, flows through the heat dissipation air duct, and then flows out from the air outlet hole. Through continuous heat exchange, the mowing motor and the driver are cooled together, and the heat dissipation cost is low.

The above are only implementations of the present disclosure and do not limit the scope of the present disclosure. Any equivalent structural changes made using the content of the present disclosure and drawings, or direct or indirect application in other related technical fields, are also included in the scope of patent protection of the present disclosure.

What is claimed is:

1. A cell housing, comprising a housing, wherein:
four corners of the housing are detachably connected to respective anti-collision members each comprising a first transverse anti-collision part, a vertical anti-collision part, and a second transverse anti-collision part;
the vertical anti-collision part is configured to surround a side of the housing; and
the first transverse anti-collision part and the second transverse anti-collision part extend horizontally, from an upper end and a lower end of the vertical anti-collision part, in a direction away from the vertical anti-collision part, and are configured to surround the upper and lower ends of the housing, respectively.

2. The cell housing according to claim 1, wherein a middle of the vertical anti-collision part is provided with a vertical positioning hole, a corresponding position on the housing is provided with a vertical positioning protrusion, and the vertical positioning protrusion is engaged in the vertical positioning hole.

3. The cell housing according to claim 2, wherein each of the first transverse anti-collision part and the second transverse anti-collision part is provided with a limit hole corresponding to a limit protrusion of the housing, and the limit protrusion is engaged in the limit hole.

4. The cell housing according to claim 3, wherein the first transverse anti-collision part extends downward to form a first positioning column, the housing is provided with a first positioning hole corresponding to the first positioning column, and the first positioning column is engaged in the first positioning hole.

5. The cell housing according to claim 4, wherein the second transverse anti-collision part extends upward to form a second positioning column, the housing is provided with a second positioning hole corresponding to the second positioning column, and the second positioning column is engaged in the second positioning hole.

6. The cell housing according to claim 1, further comprising a handle, wherein the handle is arranged at a middle of the upper end of the housing, a fixing plate corresponding to the handle is arranged inside the housing, and the handle passes through the housing and is fixedly connected to the fixing plate.

7. The cell housing according to claim 1, wherein:
a plurality of reinforcing ribs are arranged on an inner side of a top of the housing, at least one vent hole is arranged at a bottom of the housing, and the at least one vent hole is configured for heat dissipation inside the housing; and
the plurality of reinforcing ribs are arranged side by side to form an air duct, and the air duct is configured to guide air to flow out of the housing.

8. The cell housing according to claim 1, further comprising a button and a light guide post, wherein:
the button and the light guide post are located within the housing;
the button is engaged in the light guide post;
upper ends of the button and the light guide post are exposed on an upper surface of the housing; and
the button is configured to control on-off of a battery, and the light guide post is configured to display an operating state of the battery.

9. The cell housing according to claim 1, wherein the cell housing is configured to accommodate a cell within the cell housing to form a battery.

10. The cell housing according to claim 9, wherein the battery is configured for installation in a lawn mower.

11. A heat dissipation assembly for a lawn mower, comprising a heat dissipation housing and heat dissipation fan blades, wherein:
the heat dissipation housing comprises a first chamber and a second chamber adjacent to the first chamber, the first chamber is configured to arrange a mowing motor of the lawn mower, and the second chamber is configured to arrange a driver of the mowing motor;
the heat dissipation fan blades are connected to an output shaft of the mowing motor, an air inlet hole is arranged on the heat dissipation housing outside the second chamber, and a heat dissipation air duct communicates with the mowing motor and the driver;
an air outlet hole is arranged on the heat dissipation housing at a lower end of the mowing motor; and
the heat dissipation fan blades are configured to direct airflow entering through the air inlet hole through the heat dissipation air duct and then flow out from the air outlet hole.

12. The heat dissipation assembly according to claim 11, wherein a mounting frame is arranged within the second chamber, and the mounting frame is configured to mount the driver.

13. The heat dissipation assembly according to claim 12, wherein:
a heat sink is arranged on the mounting frame adjacent to the driver, the heat sink is configured to dissipate heat from the driver, and a plurality of first sub-air ducts are arranged on the heat sink; and
the heat dissipation fan blades are configured to direct airflow entering through the air inlet hole through the first sub-air ducts and then flow out from the air outlet hole.

14. The heat dissipation assembly according to claim 11, wherein the heat dissipation fan blades comprise a base plate portion and a plurality of blade portions, the blade portions are uniformly and intermittently distributed on the base plate portion, and the blade portions extend in a direction towards the mowing motor.

15. The heat dissipation assembly according to claim 14, wherein a connection hole is arranged at a center of the base plate portion, the connection hole is configured to connect the output shaft of the mowing motor, and a height of one of the plurality of blade portions adjacent to the connection hole is greater than a height of the blade portion farther from the connection hole.

16. The heat dissipation assembly according to claim 11, wherein the heat dissipation housing comprises an upper housing and a lower housing, the upper housing covers the lower housing from above, and the upper housing is detachably connected to the lower housing.

17. The heat dissipation assembly according to claim 16, wherein a sealing ring is arranged between the upper housing and the lower housing.

18. A mowing assembly, comprising a heat dissipation assembly that comprises a heat dissipation housing and heat dissipation fan blades, a mowing motor, a driver, and a mowing blade, wherein:
the heat dissipation housing comprises a first chamber and a second chamber adjacent to the first chamber, the first chamber is configured to arrange the mowing motor of a lawn mower, and the second chamber is configured to arrange the driver of the mowing motor electrically connected to the mowing motor, the driver being configured to control an operation of the mowing motor;
the heat dissipation fan blades are connected to an output shaft of the mowing motor, an air inlet hole is arranged on the heat dissipation housing outside the second chamber, and a heat dissipation air duct communicates with the mowing motor and the driver;
an air outlet hole is arranged on the heat dissipation housing at a lower end of the mowing motor;
the heat dissipation fan blades are configured to direct airflow entering through the air inlet hole through the heat dissipation air duct and then flow out from the air outlet hole; and
the mowing blade and the heat dissipation fan blades are connected to the output shaft of the mowing motor, the heat dissipation fan blades are adjacent to the mowing motor, and the mowing blade is farther from the mowing motor.

19. The mowing assembly according to claim 18, wherein a plurality of second sub-air ducts are arranged within the mowing motor, the plurality of second sub-air ducts run through the mowing motor from top to bottom, and the second sub-air ducts are configured to dissipate heat from the mowing motor.

20. The mowing assembly according to claim 18, wherein the mowing assembly is configured for installation in the lawn mower.
